(19) United States
(12) Patent Application Publication
(10) Pub. No.: US 2016/0027912 A1
(43) Pub. Date: Jan. 28, 2016

(54) SEMICONDUCTOR DEVICE AND MANUFACTURING METHOD THEREOF

(71) Applicant: KABUSHIKI KAISHA TOSHIBA, Tokyo (JP)

(72) Inventor: Hidetoshi ASAHARA, Ibo Hyogo (US)

(21) Appl. No.: 14/631,249

(22) Filed: Feb. 25, 2015

(30) Foreign Application Priority Data
Jul. 28, 2014 (JP) 2014-152690

(51) Int. Cl. H01L 29/78; H01L 29/66

(52) U.S. Cl. CPC H01L 29/7809; H01L 29/7813; H01L 29/66734

(57) ABSTRACT

A semiconductor device includes a first semiconductor region of a first conductivity type and a second semiconductor region of a second conductivity type. The second semiconductor region is adjacent to the first semiconductor region in a first direction. A third semiconductor region of the first conductivity type is adjacent to the second semiconductor region in the first direction. A first electrode is in contact with the first semiconductor region, the second semiconductor region, and the third semiconductor region via a first insulating film. A second electrode is directly adjacent to the third semiconductor region in the first direction. And a third electrode has a plurality of first connection regions that each extend along the first direction from a top surface of the first semiconductor region into the first semiconductor region. The third electrode is in contact with the first semiconductor region and spaced apart from the second electrode.

### CROSS-REFERENCE TO RELATED APPLICATION

This application is based upon and claims the benefit of priority from Japanese Patent Application No. 2014-152690, filed Jul. 28, 2014, the entire contents of which are incorporated herein by reference.

### FIELD

Embodiments described herein relate to a semiconductor device and a manufacturing method thereof.

### BACKGROUND

In semiconductor devices, such as Metal Oxide Semiconductor Field Effect Transistors (MOSFET), there is a type of transistor in which both a source electrode and a drain electrode are provided on the same side of a semiconductor device substrate (for example, on the upper surface of the substrate). In this type of semiconductor device, the drain electrode is formed extending into a semiconductor layer in order to reduce ON resistance as much as possible. In this case, a trench for forming the drain electrode is formed wide and deep in the semiconductor layer.

A manufacturing process of forming a source electrode and a drain electrode in this type of semiconductor device may proceed, for example, as follows. At first, after forming a trench in a semiconductor layer, an electrode layer is formed inside and outside the trench. Then, a resist layer is formed on the electrode layer. The resist layer is patterned to make a mask for separating the electrode layer into the source electrode and the drain electrode. This patterning uses a photolithographic technique.

However, a wide and deep trench may alter the deposited film thickness of the resist layer and may cause the evenness of the resist film thickness to vary across the substrate. Thus, when exposure is performed on the uneven resist layer, there is a possibility of an exposure variation occurring in some part of the resist layer making uniform resist patterning difficult.

### DESCRIPTION OF THE DRAWINGS

FIG. 1A is a schematic plan view illustrating a semiconductor device according to a first embodiment.

FIGS. 1B and 1C are schematic cross-sectional views illustrating the semiconductor device according to the first embodiment.

FIG. 2A to FIG. 8 are schematic cross-sectional views illustrating the process of manufacturing the semiconductor device according to the first embodiment.

FIG. 9A to FIG. 10B are schematic cross-sectional views illustrating the process of manufacturing a semiconductor device according to a reference example.

FIG. 11A is a schematic plan view of a semiconductor device of a first example according to a second embodiment.

FIG. 11B is a schematic plan view of a semiconductor device of a second example according to the second embodiment.

FIG. 12A is a schematic plan view of a semiconductor device of a first example according to a third embodiment.

FIG. 12B is a schematic plan view of a semiconductor device of a second example according to the third embodiment.

### DETAILED DESCRIPTION

According to an embodiment, a semiconductor device includes a first semiconductor region of a first conductivity type and a second semiconductor region of a second conductivity type adjacent to the first semiconductor region in a first direction. A third semiconductor region of the first conductivity type is adjacent to the second semiconductor region in the first direction. A first electrode is provided that is in contact with the first semiconductor region, the second semiconductor region, and the third semiconductor region via a first insulating film. A second electrode is provided that is directly adjacent to the third semiconductor region in the first direction. A third electrode having a plurality of first connection regions that each extend along the first direction from a top surface of the first semiconductor region into the first semiconductor region is also provided. The third electrode is in contact with the first semiconductor region and spaced apart from the second electrode.

Hereinafter, example embodiments will be described with reference to the drawings. In the following description, like reference numerals are used to refer to like members, the explanation will be properly omitted as for elements having been previously explained.

### First Embodiment

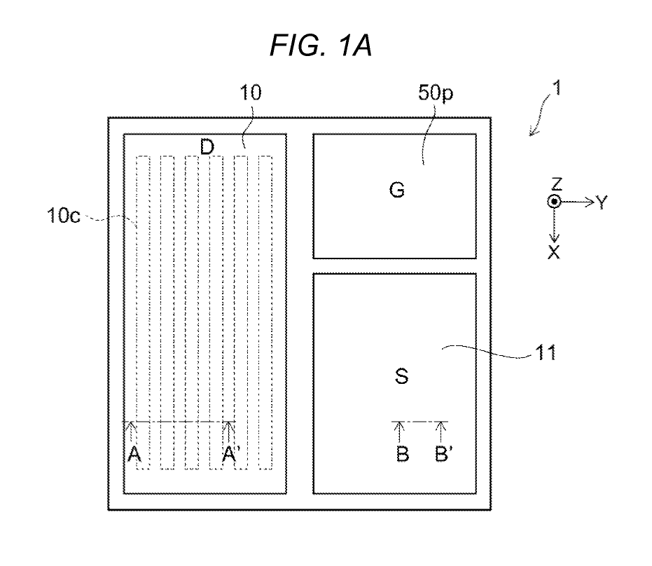

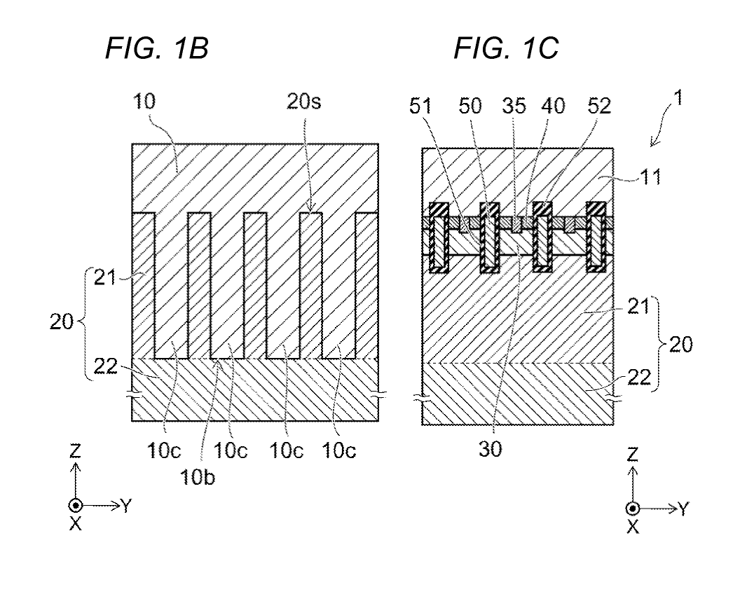

FIG. 1A is a schematic plan view illustrating a semiconductor device according to a first embodiment and FIGS. 1B and 1C are schematic cross-sectional views illustrating the semiconductor device according to the first embodiment.

Here, FIG. 1B illustrates a cross section taken along the line of A-A′ of FIG. 1A and FIG. 1C illustrates a cross section taken along the line B-B′ of FIG. 1A.

A semiconductor device 1 according to the first embodiment is an up-drain MOSFET with the drain electrode provided on a side of the upper surface of the semiconductor device. The semiconductor device 1 in this example has a structure of Wafer Level Chip Scale Package (WCSP). The semiconductor device 1 has a first semiconductor region 20 (hereinafter, a semiconductor region 20). The semiconductor region 20 includes an n⁺-type first region 22 and an n-type second region 21 provided on the first region 22.

Here, the first region 22 is a drain region. The second region 21 is a drift region. The dopant concentration of the second region 21 is lower than that of the first region 22. The second region 21 is an epitaxial growth layer in this example. The thickness of the second region 21 is, for example, about 5 μm. The thickness of the first region 22 is, for example, about 100 μm.

A p-type second semiconductor region 30 (hereinafter, referred to as, for example, a semiconductor region 30) is provided on the semiconductor region 20. The semiconductor region 30 is a base region. An n⁺-type third semiconductor region 40 (hereinafter, referred to as a semiconductor region 40) is provided on the semiconductor region 30. The semiconductor region 40 is a source region. A first electrode 50 (hereinafter, referred to as a gate electrode 50) is in contact with the semiconductor region 20, the semiconductor region 30, and the semiconductor region 40 through a first insulating film 51 (hereinafter, referred to as a gate insulating film 51). The gate electrode 50 extends in a direction of X (X-direction) in the drawings.

An electrode 11 is provided on the semiconductor region 40. The electrode 11 is in contact with the semiconductor region 40. The electrode 11 is a source electrode. A p⁺-type semiconductor region 35 is provided between the semiconductor region 30 and the electrode 11. The semiconductor region 35 is a so-called “hole extraction region.” An interlayer insulating film 52 is provided between the gate electrode 50 and the electrode 11.

A third electrode 10 (hereinafter, referred to as an electrode 10) is provided on the semiconductor region 20 at a distance from the electrode 11 (e.g., electrode 10 is spaced apart from electrode 11 in the Y-direction of FIG. 1A. The electrode 10 is a drain electrode. The electrode 10 includes a plurality of first connection regions 10c (hereinafter, referred to as a connection region 10c) extending from surface 20s of the semiconductor region 20 in to the inner portion of the semiconductor region 20.

The plurality of connection regions 10c are in contact with the semiconductor region 20. The bottoms 10b of the plurality of connection regions 10c contact the first region 22. The width (in the Y-direction) of each connection region 10c is larger than that of the gate electrode 50. The plurality of connection regions 10c extend in a direction (X-direction) crossing a direction (Z-direction) from the semiconductor region 20 to the semiconductor region 30. Further, an electrode 50p illustrated in FIG. 1A is a gate pad. The electrode 50p is electrically connected to the gate electrode 50.

The ON resistance of the semiconductor device 1 is reduced by these connection regions 10c extending through the second region 21, which has a higher resistance than that of the first region 22, and making contact with the lower resistance first region 22.

The material of the semiconductor region according to the first embodiment may be, for example, silicon (Si), silicon carbide (SiC), and gallium arsenide (GaAs). The material of the electrodes 10, 11, 50p, and the connection region 10c may be, for example, a metal including at least one of aluminum (Al), nickel (Ni), copper (Cu), and titanium (Ti), or an electric conductor such as polysilicon. The material of the gate electrode 50 includes a semiconductor to which a dopant is introduced (for example, polysilicon) or metal (for example, tungsten). Furthermore, the “insulating film” according to the first embodiment includes silicon dioxide (SiOx) and silicon nitride (SiNx).

In the first embodiment, n⁺-type and n-type may be referred to as a first conductivity type and p⁺-type and p-type may be referred to as a second conductivity type. Further, the dopant concentration is decreased in the order of n⁺-type and n-type and also in the order of p⁺-type and p-type.

The dopant element of the n⁺-type and the n-type includes, for example, phosphorus (P) and arsenide (As). The dopant element of the p⁺-type and the p-type includes, for example, boron (B).

A process of manufacturing the semiconductor device 1 will be described.

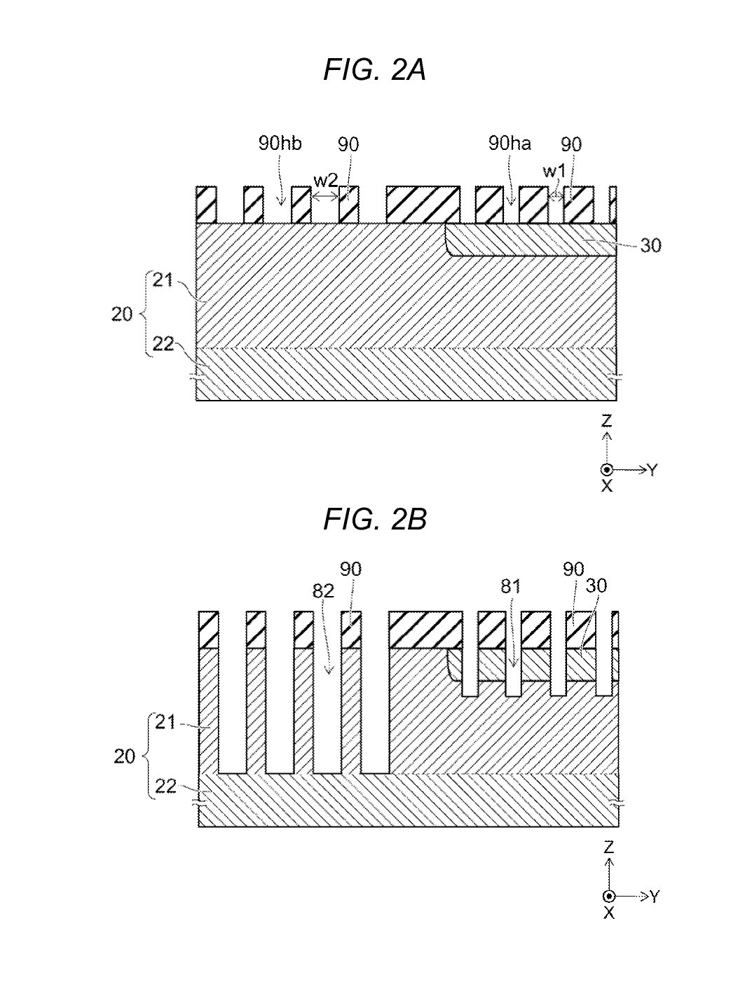

FIGS. 2A to 8 are schematic cross-sectional views illustrating the process of manufacturing the semiconductor device according to the first embodiment. In each of FIGS. 2A to 8, a region where a transistor and the electrode 11 are formed and a region where the electrode 10 is formed are shown together in the same figure.

As illustrated in FIG. 2A, a mask layer 90 is formed on the upper side of the semiconductor region 20. The mask layer 90 includes a second opening 90ha (hereinafter, referred to as an opening 90ha) having a first width w1 (hereinafter, referred to as a width w1) and a third opening 90hb (hereinafter, referred to as an opening 90hb) having a second width w2 wider than the width w1. In the first embodiment, the “width” means a width in the Y-direction in the drawings. A plurality of the openings 90hb is formed.

The semiconductor region 30 is formed on the semiconductor region 20 in a region where the trench gate is formed. For example, in the region where the trench gate is formed, a p-type dopant element is selectively injected in the top layer of the semiconductor region 20 and the annealing process is performed there, hence to form the p-type semiconductor region 30.

As illustrated in FIG. 2B, by removing the semiconductor region 20 under the opening 90ha, a first trench 81 (hereinafter, referred to as, for example, a trench 81) is formed in the semiconductor region 20. By removing the semiconductor region 20 under the plurality of openings 90hb, a plurality of second trenches 82 (hereinafter, referred to as trenches 82) are formed in the semiconductor region 20. The removal of the semiconductor region 20 is performed through Reactive Ion Etching (RIE).

The trench 81 and the trenches 82 are formed from a side of the top surface of the semiconductor region 20 toward a side of the rear surface thereof. Here, the width w1 of the opening 90ha of the mask layer 90 is narrower than the width w2 of the opening 90hb of the mask layer 90. Accordingly, when the trenches 81 and 82 are formed simultaneously, the width of the trench 82 (width in the Y direction) becomes larger than the width of the trench 81 (width in the Y direction) and the depth of the trench 82 becomes larger than the depth of the trench 81 through microloading effects. As for the trench 82, etching is performed deep to expose the first region 22 at a bottom of the trench 82.

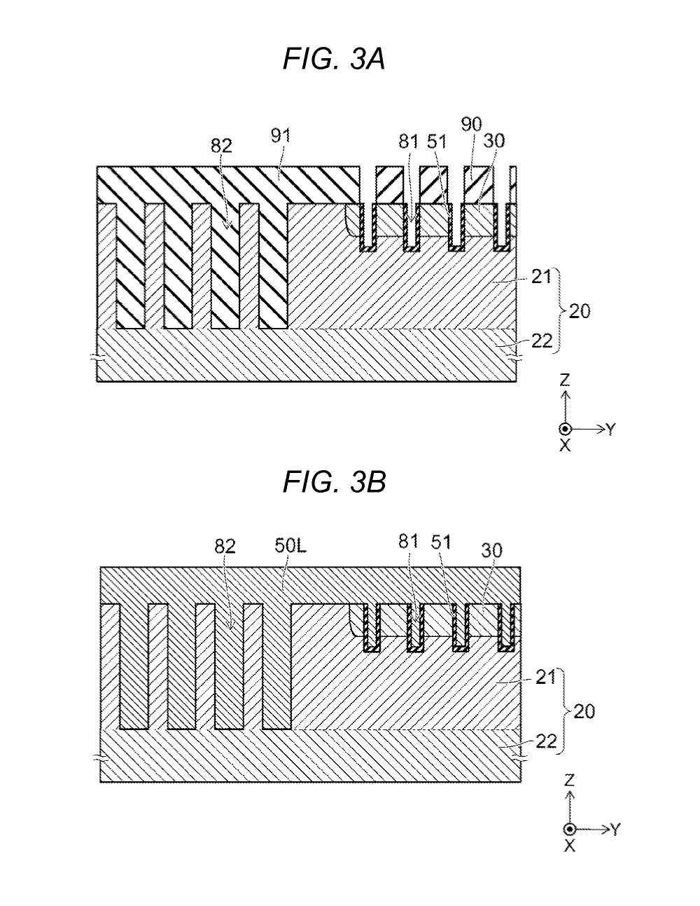

As illustrated in FIG. 3A, a mask layer 91 covers the inner portions of the trenches 82 and the semiconductor region 20 and a gate insulating film 51 is formed on the inner wall of the trench 81. The gate insulating film 51 is formed, for example, according to Chemical Vapor Deposition (CVD) or Atomic Layer Deposition (ALD). Then, the mask layer 91 is removed.

Next, as illustrated in FIG. 3B, an electrode layer 50L is formed within the trench 81 and on the semiconductor region 30 as well as within the trenches 82 and on the semiconductor region 20. This electrode layer 50L makes the gate electrode 50.

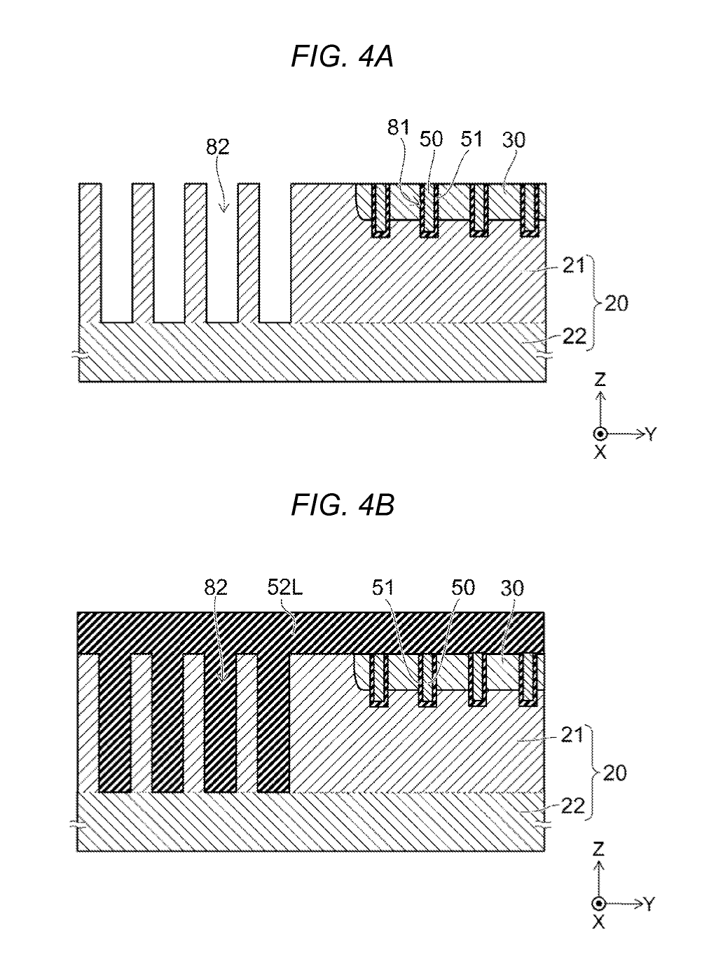

For example, as illustrated in FIG. 4A, the electrode layer 50L is left within the trench 81 after Chemical Mechanical Polishing (CMP), photolithography and etching. The electrode layer 50L is removed from the trenches 82. According to this, the gate electrode 50 is formed within the trench 81 through the gate insulating film 51.

Next, as illustrated in FIG. 4B, an insulating layer 52L covers the inner portions of the trenches 82 and the semiconductor region 20 and at the same time, the insulating layer 52L is formed on the gate electrode 50, the gate insulating film 51, and the semiconductor region 30.

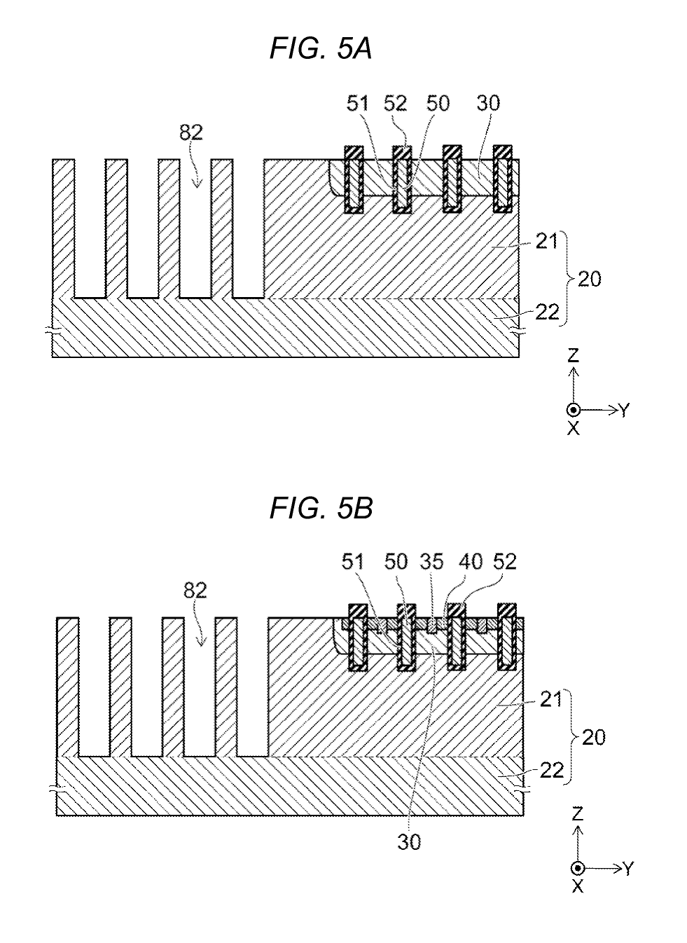

Next, as illustrated in FIG. 5A, CMP, photolithography and etching are used to leave the insulating layer 52L on the gate electrode 50 and the gate insulating film 51. According to this, an interlayer insulating film. 52 is formed on the gate electrode 50 and the gate insulating film 51.

Next, as illustrated in FIG. 5B, an n-type dopant element is injected in the top layer of the semiconductor region 30, to form an n⁺-type semiconductor region 40 on the semiconductor region 30. Further, Photo Engraving Process (PEP) technique and ion injection are used to form a p⁺-type semiconductor region 35 on the semiconductor region 30.

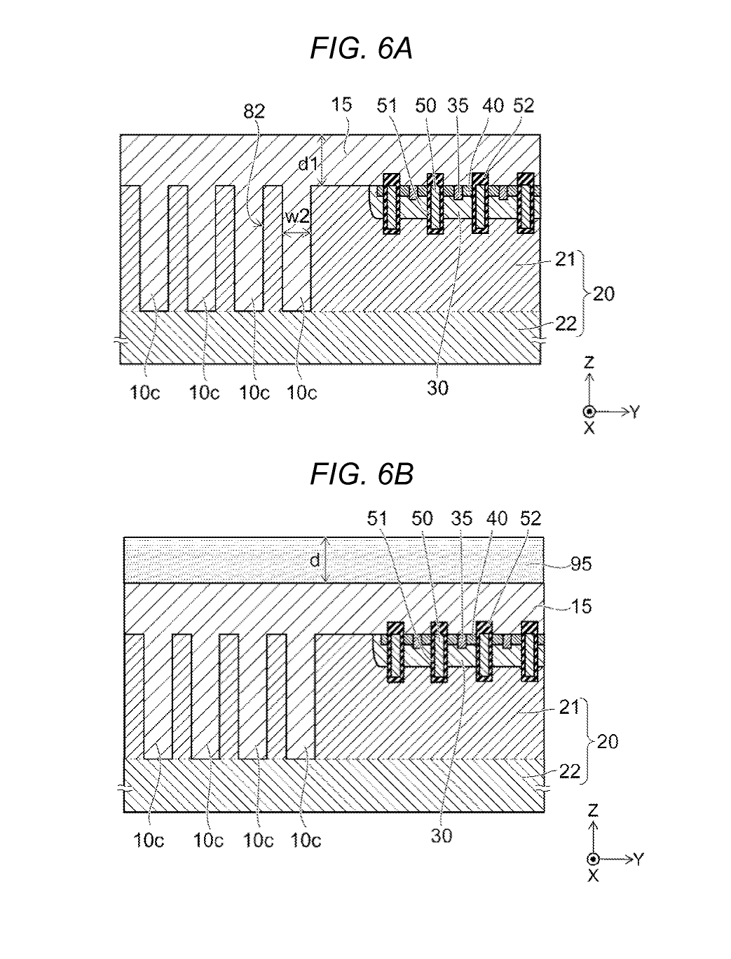

Next, as illustrated in FIG. 6A, an electrode layer 15 is formed within the plurality of trenches 82 and on the semiconductor region 20. Here, the electrode layer 15 is in contact with the semiconductor region 40. The electrode layer 15 is formed according to Physical Vapor Deposition (PVD), CVD, or vapor deposition. The electrode layer 15 is a layer before being separated into the electrode 10 and the electrode 11. Further, the electrode layer 15 formed within the plurality of trenches 82 becomes the connection region 10c.

The width w2 of the trench 82 (or the connection region 10c) is adjusted so that a relation of the width w2 and the film thickness d1 of the electrode layer 15 may satisfy the expression of d1>(1/2)·w2. Accordingly, the electrode layer 15 is formed within the plurality of trenches 82 and on the semiconductor region 20.

Next, as illustrated in FIG. 6B, a resist layer 95 is formed on the electrode layer 15. The resist layer 95 is, for example, a negative-tone resist layer. Here, the film thickness d of the resist layer 95 formed on the electrode layer becomes more even compared with reference examples described later.

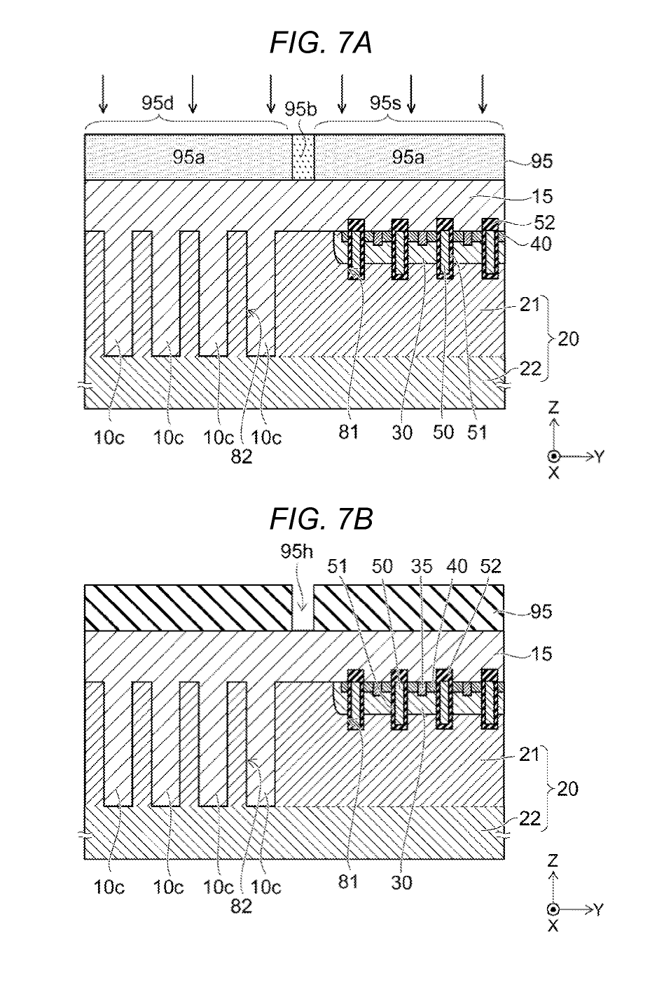

As illustrated in FIG. 7A, a mask pattern is formed on the electrode layer 15 in order to separate the electrode layer 15 into the electrode 10 and the electrode 11 according to the RIE. For example, when the negative-tone resist layer 95 is used, a region 95d of the resist layer 95 covering the plurality of connection regions 10c and a region 95s of the resist layer 95 covering the gate electrode 50 are irradiated with exposure light selectively. According to this, a cured portion 95a, cured by irradiation of exposure light and an unexposed/uncured portion 95b are formed in the resist layer 95.

Then, as illustrated in FIG. 7B, the resist layer 95 is developed to remove the unexposed portion 95b. According to this, the resist layer 95 having a first opening 95h (hereinafter, referred to as, for example, an opening 95h) is formed on the electrode layer 15. The opening 95h is positioned between the plurality of trenches 82 and the trench 81.

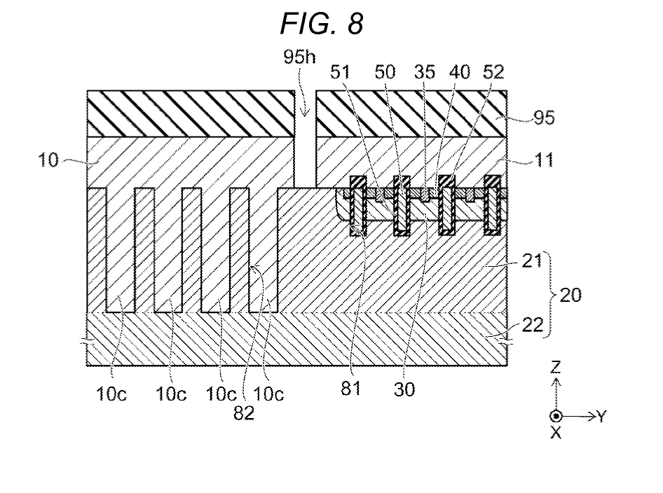

As illustrated in FIG. 8, the electrode layer 15 in the opening 95h is removed according to the RIE. According to this, the electrode layer 15 is separated, to form the electrode 11 on the gate electrode 50 and form the electrode 10 in parallel to the electrode 11. The electrode 10 and the electrode 11 are aligned at a distance. The electrode 10 includes an electrode layer (connection regions 10c) provided within the plurality of trenches 82.

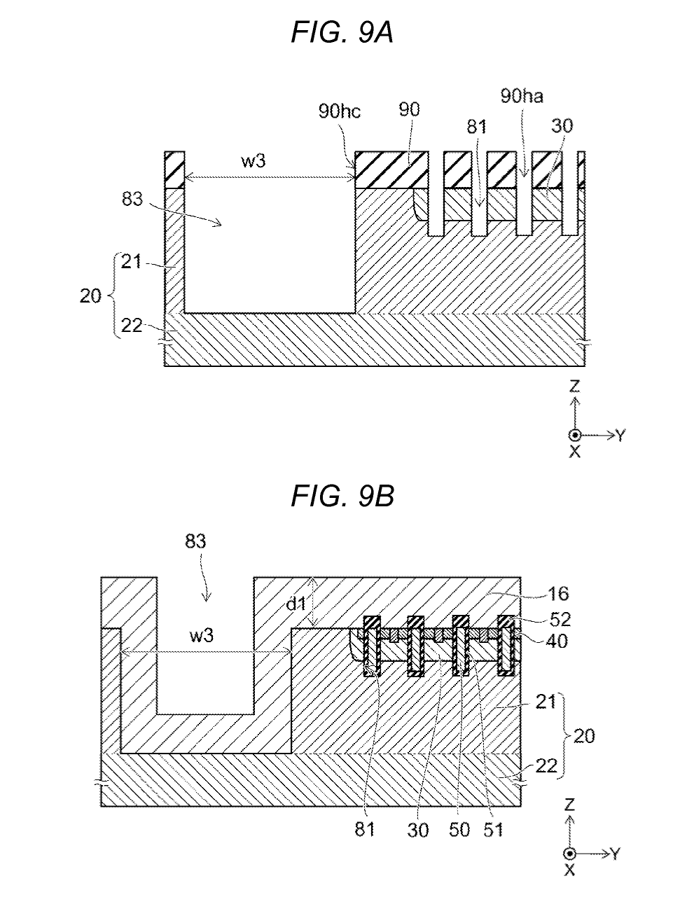

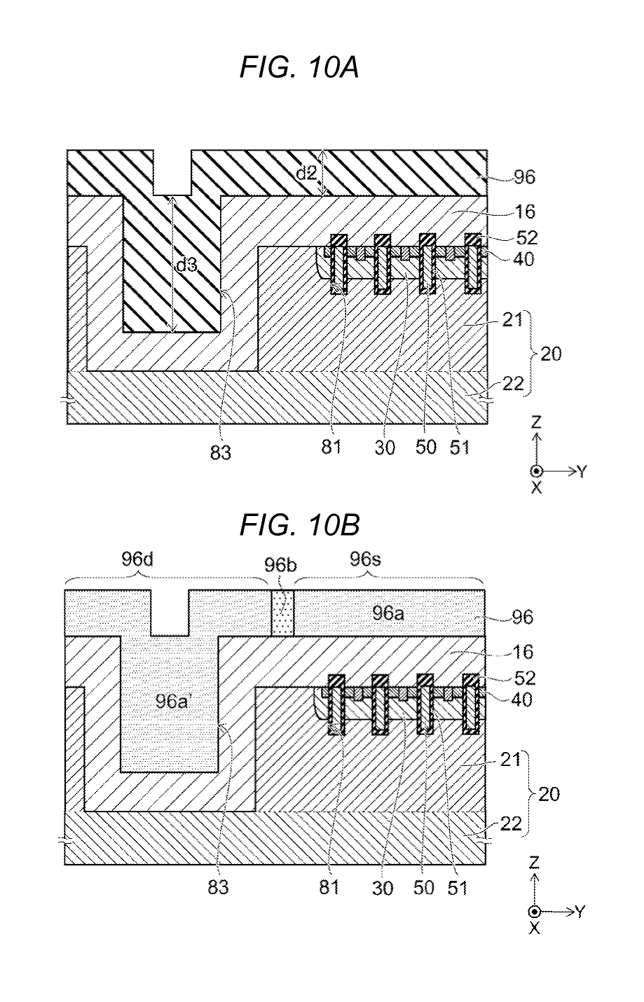

FIGS. 9A to 10B are schematic cross-sectional views illustrating the process of manufacturing a semiconductor device according to a reference example.

In the reference example, only one trench 83 is formed to perform the process of forming a drain electrode instead of forming a plurality of trenches 82.

For example, as illustrated in FIG. 9A, as a trench forming a drain electrode, a trench 83 is formed on the semiconductor region 20. Here, the width w3 of an opening 90hc of the mask layer 90 in the Y direction is larger than the width w2 of the opening 90hb.

As illustrated in FIG. 9B, an electrode layer 16 is formed within the trench 83 and on the semiconductor region 20. The electrode layer 16 is formed according to the PVD, CVD, and vapor deposition. The electrode layer 16 is a layer before being it is separated into the electrode 10 and the electrode 11.

Here, the width of the trench 83 is larger than that of the trench 82. For example, the width w3 of the trench 83 is adjusted so that a relation of the width w3 and the film thickness d1 of the electrode layer 16 may satisfy the expression of d1<(1/2)·w3. Accordingly, the electrode layer 16 is formed along the inner wall of the trench 83 and further formed on the semiconductor region 20.

Here, a state in which a resist layer is formed on the electrode layer 16 is illustrated in FIG. 10A. The resist layer is, for example, a negative-tone resist layer.

As illustrated in FIG. 10A, the film thickness (Z-direction) of the resist layer 96 is not even as contrasted with the resist layer 95 according to the first embodiment. For example, the resist layer 96 has the film thickness d2 and the film thickness d3. The film thickness d3 is larger than the film thickness d2.

As illustrated in FIG. 10B, a mask pattern for separating the electrode layer 16 into the electrode 10 and the electrode 11 is formed. For example, a region 96d of the resist layer 96 where a drain electrode of up-drain type is formed and a region 96s of the resist layer 96 covering the gate electrode 50 are irradiated with exposure light selectively. According to this, a cured portion 96a by irradiation of exposure light and an unexposed/uncured portion 96b are formed in the resist layer 96.

In the portion 96a′ of the region 96d, however, the resist film thickness is large. Therefore, in the portion 96a′, there is a possibility of exposure shortage happening. Here, the exposure shortage means that the exposure light amount per unit area in the resist layer is less than an amount required to cure the negative-tone resist to make it insoluble in developer. Thereafter, when the resist layer 96 is developed, the portion 96a′ short of exposure may be also unintentionally removed, in addition to the portion 96b. In short, in the reference example, there is a possibility that a mask pattern for separating the electrode layer 16 into the electrode 10 and the electrode 11 is not successfully formed.

On the contrary, in the first embodiment, the width w2 of the trench 82 is adjusted so that a relation of the w2 and the film thickness d1 of the electrode layer 15 may satisfy the expression of d1>(1/2)·w2. Accordingly, in the first embodiment, the electrode layer 15 is not formed along the inner wall of the trench 82 but is formed within the trench 82 to fill the trench 82, and further it is formed also on the semiconductor region 20 exposed at the bottom of trench 20.

Accordingly, the resist layer 95 formed on the electrode layer 15 has an even film thickness compared with the reference example (resist layer 96). In short, a partial exposure shortage of the resist layer 95 is unlikely to occur. According to this, a mask pattern for separating the electrode layer 15 into the electrode 10 and the electrode 11 may be more assuredly formed.

Additionally, the electrode 10 includes a plurality of connection regions 10c extending inside the semiconductor region 20. Therefore, heat generated in the semiconductor device 1 may be released outside the semiconductor device 1 through the connection regions 10c.

When the connection regions 10c are made of the same material as the gate electrode 50, then the trenches 82, the trench 81, the connection regions 10c, and the gate electrode 50 may be formed at once. That is, as for the formation of the trenches 82 and the formation of the connection regions 10c, there is no increase in the manufacturing process.

As compared with the manufacturing yield of the reference example, the manufacturing yield according to the first embodiment has been improved more than 10%.

### Second Embodiment

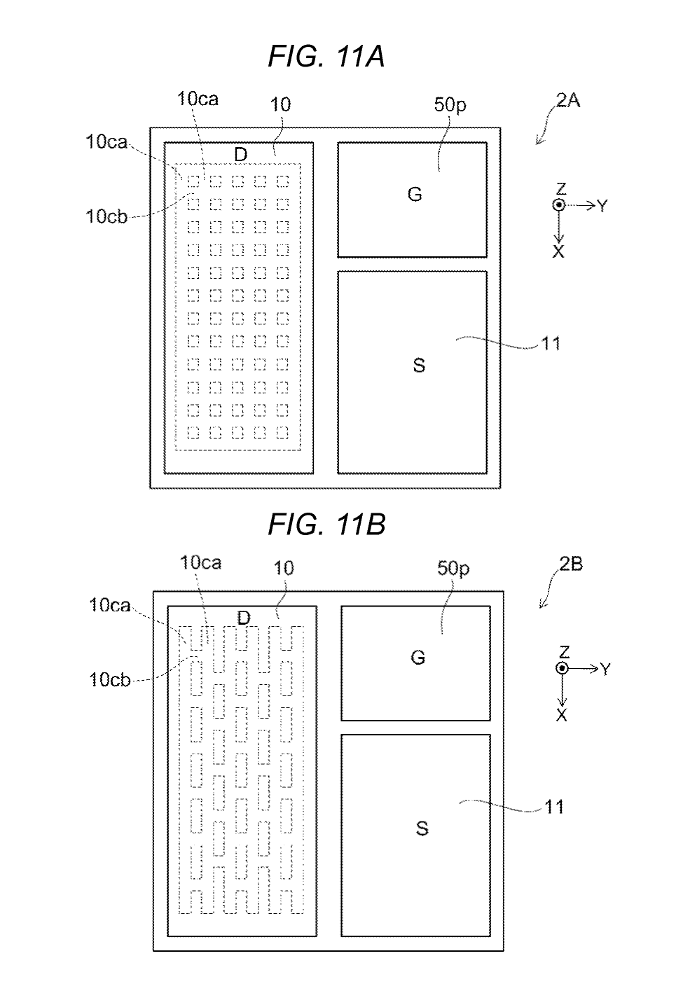

FIG. 11A is a schematic plan view of a semiconductor device according to a first example of a second embodiment, and FIG. 11B is a schematic plan view of a semiconductor device according to a second example of the second embodiment.

A semiconductor device 2A illustrated in FIG. 11A further includes a plurality of second connection regions 10cb (hereinafter, referred to as a connection region 10cb) for connecting first connection regions 10ca adjacent in the Y-direction, of a plurality of the first connection regions 10ca (hereinafter, referred to as a connection region 10ca) extending in the X-direction. Further, the pitch of the plurality of connection regions 10cb is in the same phase in the X-direction. In the second embodiment, the connection regions are in a shape of mesh or a grid pattern.

In the semiconductor device 2B illustrated in FIG. 11B, the pitch of the plurality of connection regions 10cb is in a deviated phase in the X-direction (off-set structure). For example, when some connection region 10ca is selected from the plurality of connection regions 10ca, the pitch of the connection regions 10cb in the X-direction is offset, for example, at 90° on both sides of the connection region 10ca.

In the second embodiment, as the connection region, there exist the connection regions 10cb besides the connection regions 10ca. Therefore, in the second embodiment, a resistance of the electrode 10 is further reduced and the ON resistance of the semiconductor device 2B is further reduced, in addition to the effect of the first embodiment. Further, in the second embodiment, the volume of the connection regions is increased, as compared with the first embodiment. According to this, heat generated in the semiconductor devices 2A and 2B may be efficiently released outside the semiconductor devices 2A and 2B through the connection regions 10ca and 10cb.

Further, when the connection region get narrower and thus more difficult to form via photolithography, the off-set structure illustrated in FIG. 11B may be selected rather than the structure of the connection regions illustrated in FIG. 11A to make it easier to form the connection regions at a high density.

### Third Embodiment

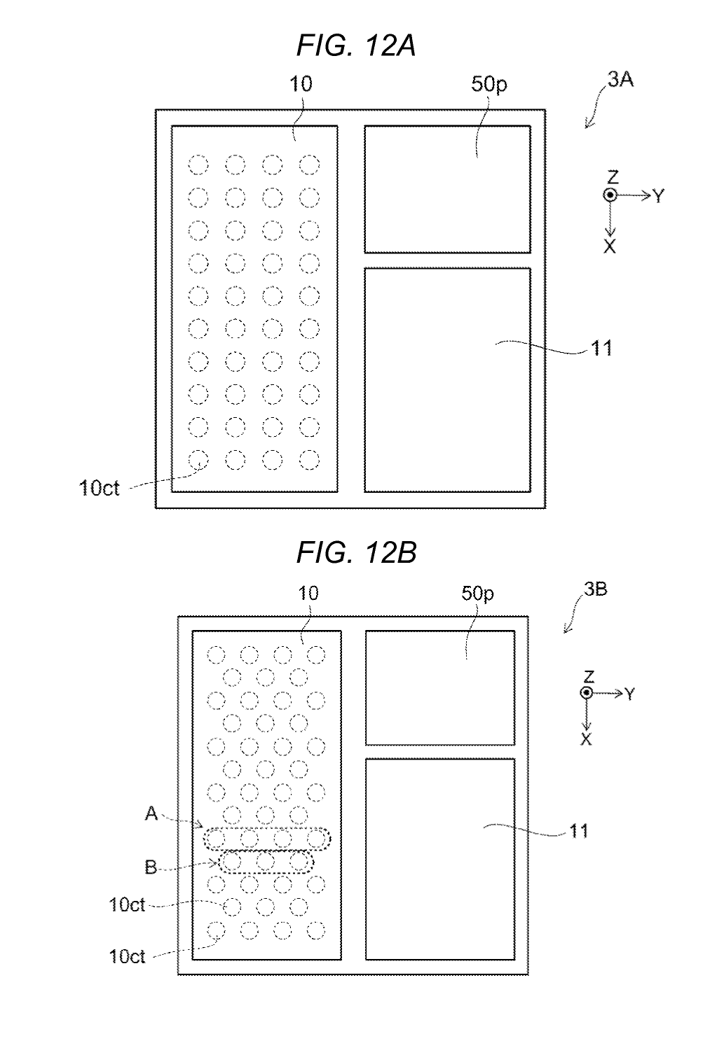

FIG. 12A is a schematic plan view illustrating a semiconductor device according to a first example of a third embodiment, and FIG. 12B is a schematic plan view illustrating a semiconductor device according to a second example of the third embodiment.

In a semiconductor device 3A illustrated in FIG. 12A, each connection region 10ct has a cylindrical shape. A plurality of connection regions 10ct are aligned respectively in the X-direction and the Y-direction. Further, the pitch of the plurality of connection regions 10ct is in the same phase in the X-direction and the Y-direction. When each of the connection regions 10ct is cut perpendicular to the Z-direction, the outer shape of each of the connection regions 10ct is, for example, circular. This structure also has the same effect as the first embodiment.

In the semiconductor device 3B illustrated in FIG. 12B, for example, the pitch of the connection regions 10ct surrounded by an arrow A is deviated (offset) from the pitch of the connection regions 10ct surrounded by an arrow B in the Y-direction (off-set structure). According to the disposition of these connection regions 10ct, the occupied area of the connection regions is more than that of the semiconductor device 3A illustrated in FIG. 12A.

Accordingly, the semiconductor device 3B may reduce the resistance of the electrode 10 more than the semiconductor device 3A and further reduce the ON resistance of the semiconductor device. Further, in the semiconductor device 3B, the number of the connection regions 10ct is increased more than in the semiconductor device 3A. According to this, heat generated in the semiconductor device 3B may be released outside the semiconductor device 3B through the connection regions 10ct more efficiently than that of the semiconductor device 3A.

As set forth hereinabove, certain embodiments of the disclosure have been described with reference to the concrete examples. The embodiments of this disclosure, however, are not restricted to these specific examples. In other words, the embodiments with a proper modification design added to these concrete examples by those skilled in the art are also included in the scope of the embodiments as far as they are provided with the characteristics of the embodiments. The respective elements, and the disposition, material, condition, shape, and size thereof included in the above-mentioned concrete examples are not restricted to those shown in the examples but they may be properly modified.

Further, the respective elements included in the respective embodiments may be combined as far as technically permitted; their combination may be included in the scope of the embodiments as far as provided with the characteristics of the embodiments. In the scope of the spirit of the embodiments, other modifications and changes that are easily arrived by those skilled in the art are also to be included in the scope of the embodiments.

While certain embodiments have been described, these embodiments have been presented by way of example only, and are not intended to limit the scope of the inventions. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor device, comprising:
a first semiconductor region of a first conductivity type;
a second semiconductor region of a second conductivity type adjacent to the first semiconductor region in a first direction;
a third semiconductor region of the first conductivity type adjacent to the second semiconductor region in the first direction;
a first electrode that is in contact with the first semiconductor region, the second semiconductor region, and the third semiconductor region via a first insulating film;
a second electrode that is directly adjacent to the third semiconductor region in the first direction; and
a third electrode having a plurality of first connection regions that each extend along the first direction from a top surface of the first semiconductor region into the first semiconductor region, the third electrode in contact with the first semiconductor region and spaced apart from the second electrode.

2. The semiconductor device according to claim 1, wherein
the first semiconductor region includes a first portion and a second portion adjacent to the first portion in the first direction, the first portion having a dopant concentration greater than a dopant concentration of the second portion, and
the plurality of first connection regions is directly adjacent to the first portion in the first direction.

3. The semiconductor device according to claim 2, wherein
the second and third electrodes are spaced apart from each other in a second direction that is parallel to the top surface and perpendicular to the first direction, and the plurality of first connection regions extend in a third direction orthogonal to the first and second directions.

4. The semiconductor device according to claim 1, wherein
the second and third electrodes are spaced apart from each other in a second direction that is parallel to the top surface and perpendicular to the first direction, and the plurality of first connection regions extend in a third direction orthogonal to the first and second directions.

5. The semiconductor device according to claim 1, wherein
the second and third electrodes are spaced apart from each other in a second direction that is parallel to the top surface and perpendicular to the first direction,
each first connection region has a width along the second direction that is larger than a width along the second direction of the first electrode.

6. The semiconductor device according to claim 5, further comprising:
a plurality of second connection regions connecting the first connection regions that are adjacent to each other in the second direction.

7. The semiconductor device according to claim 4, further comprising:
a plurality of second connection regions connecting the first connection regions that are adjacent to each other in the second direction.

8. The semiconductor device according to claim 7, wherein second connection regions adjacent to each other in the second direction are offset from each other along a third direction parallel to the top surface and orthogonal to the first and second direction.

9. The semiconductor device according to claim 1, wherein
at least one first connection region in the plurality of first connection regions has a circular shape in a plane parallel to the top surface.

10. The semiconductor device according to claim 1, wherein the plurality of first connection regions is a plurality of cylinders each extending in the first direction, the plurality of cylinders disposed in a plane parallel to the top surface in a regularly spaced array.

11. The semiconductor device according to claim 9, wherein the regularly spaced array includes adjacent rows of cylinders that are offset along a second direction along the top surface and perpendicular to the first direction.

12. A semiconductor device, comprising:
a first semiconductor region of a first conductivity type;
a plurality of first electrodes disposed on the first semiconductor region via first insulating layer;
a second electrode disposed on the first semiconductor region between the plurality of first electrodes; and
a third electrode disposed on the first semiconductor region and including a plurality of first connection portions extending in a first direction from a first surface of the first semiconductor region into the first semiconductor region, the third electrode being spaced apart from the second electrode in a direction that is parallel to the first surface and perpendicular the first direction.

13. The semiconductor device according to claim 12, wherein
the first semiconductor region includes a first portion and a second portion adjacent to the first portion in the first direction, the first portion having a dopant concentration greater than a dopant concentration of the second portion,
the plurality of first connection portions being directly adjacent to the first portion in at least the first direction and directly adjacent to the second portion in at least the second direction.

14. The semiconductor device according to claim 12, wherein the plurality of first connection portions are cylinders.

15. The semiconductor device according to claim 12, wherein the third electrode further comprises:
a plurality second connection portions connecting adjacent first connection portions in the second direction.

16. The semiconductor device according to claim 15, wherein second connection portions adjacent to each other in the second direction are offset from each other in a third direction parallel to the first surface and orthogonal to the first and second directions.

17. A method of manufacturing a semiconductor device, comprising:
forming a first trench and a plurality of second trenches, the second trenches being deeper in a first direction and wider in a second direction than the first trench, the first trench and the plurality of second trenches each extending in a third direction that is orthogonal to the first and second direction from a first surface into first semiconductor region of a first conductivity type;
forming a first electrode in the first trench, the first electrode contacting the first semiconductor region via a first insulating film;
forming an electrode layer in the plurality of second trenches and covering the first insulating film and the first semiconductor region;
forming a resist layer on the electrode layer;
forming a first opening in the resist layer at a position between, in the second direction, the plurality of second trenches and the first trench; and
removing a portion of the electrode layer exposed at the first opening to form a second electrode including the electrode layer on the first insulating film and the first semiconductor region that is adjacent to the first electrode and to form a third electrode including the electrode layer in the plurality of second trenches, the second and third electrodes being electrically separated from each other.

18. The method according to claim 17, wherein
forming the first trench and the plurality of second trenches includes:
forming a mask layer including a second opening with a first width and a plurality of third openings with a second width wider than the first width on the first semiconductor region; and
forming the first trench by removing the first semiconductor region under the second opening, and forming the plurality of second trenches by removing the first semiconductor region under the plurality of third openings.

19. The method of claim 17, wherein the first semiconductor region includes a first portion and a second portion adjacent to the first portion in the first direction, the first portion having a dopant concentration greater than a dopant concentration of the second portion, and
the plurality of second trenches extends in the first direction through the second portion and reaches the first portion.

20. The method according to claim 17, wherein the plurality of second trenches comprise cylinders.
